(19) United States
(12) Patent Application Publication
(10) Pub. No.: US 2011/0304244 A1
(43) Pub. Date: Dec. 15, 2011

(54) Adjustable rail mounting system

(75) Inventors: Carl Cottuli, Franklin, MA (US); Richard Latino, Sterling, MA (US)

(73) Assignee: Eaton Corporation, Cleveland, OH (US)

(21) Appl. No.: 13/134,583

(22) Filed: Jun. 8, 2011

Related U.S. Application Data
(60) Provisional application No. 61/353,198, filed on Jun. 9, 2010.

(51) Int. Cl. H05K 5/02; H05K 7/14

(52) U.S. Cl. 312/223.1; 211/26

(57) ABSTRACT

Horizontally-mounted rail tracks are adjustably coupled to vertical rack mount rails with slidable connectors. The rail tracks are configured to contain the connectors while allowing the connectors to traverse the length of the rail track. The connectors are coupled to the rails via a threaded stud that projects through an opening in the rail, and a pair of support tabs that protrude through slots in the rail. The rail tracks comprise positioning slots that are visible through windows on the rails. The connectors include an indicator band in a color that contrasts with the color of the rail track, such that the indicator band is visible through one the positioning slots, to enable the user to vertically align both ends of the rails with respect to the tracks. The rails are coupled to the rail tracks via index tabs that engage index slots on the rail tracks, and the rails are locked into place with threaded female connectors.

### CROSS-REFERENCE TO RELATED APPLICATION

This application claims priority to U.S. Provisional Patent Application Ser. No. 61/353,198, entitled “Adjustable Rail Mounting System,” filed on Jun. 9, 2010. The entire contents of the priority application are expressly incorporated by reference herein.

### FIELD OF THE INVENTION

The invention relates to cabinets and enclosures for housing electrical and computer equipment, and particularly to systems and assemblies for positioning, installing and adjusting vertical rack mount rails within such cabinets and enclosures.

### BACKGROUND OF THE INVENTION

Electronic equipment components, such as computer servers, routers, switches, data storage devices, and power supplies, are often mounted on vertical rails in cabinets or enclosures. These rack-mounted components and devices are available in various physical sizes, depending upon the manufacturer, and vary considerably in height and depth. In some cases, customized cabinetry is required to accommodate the many different equipment configurations, which may be expensive to purchase and maintain, and may result in a data center with multiple specialized cabinets that are not fully loaded with equipment. Note also that cabinets and enclosures are often required to satisfy one or more industry standards, such as the Electronic Industries Association (EIA) EIA-310-D standard, which defines requirements for the industry-standard nineteen-inch rack, and in particular, establishes parameters for the rail mounting-hole patterns.

There is a need, then, for cabinets and enclosures that are configurable, to accommodate the wide array of electronic components and devices. In particular, there is a need for the cabinet's vertical rack mount rails, including EIA-standard rails, to be adjustable, relative to the front and back of the cabinet, to accommodate the varying equipment depths. In addition, it is desirable for the cabinet or enclosure to have indexing features, such as visual indicators or marks, to facilitate the accurate positioning of the vertical rack mount rails relative to each other, and relative to the frame of the enclosure, to ensure that the vertical rack mount rails are plumb.

There is also a need for a mechanism that locks the vertical rack mount rails in place once they have been positioned. As is know in the art, there is a tendency for the vertical rack mount rails to shift out of position, particularly when a cabinet or enclosure that has been pre-populated with electronic equipment is shipped, and particularly when the vertical rack mount rails are secured only with a friction-type clamping mechanism.

### SUMMARY OF THE INVENTION

The invention disclosed herein provides systems and assemblies for accurately positioning, installing, and adjusting vertical rack mount rails within a cabinet or enclosure. In particular, the invention comprises a plurality of vertical rack mount rails, a plurality of horizontally-mounted rail tracks, and a plurality of slidable connectors that are configured to adjustably couple the rail tracks to the rails.

The horizontally-mounted rail tracks are adapted to support the weight of the vertical rack mount rails and their electronic equipment loads, and to facilitate the fore and aft adjustment of the vertical rack mount rails. The rail tracks are preferably mounted parallel to each other in a front-to-back orientation, along the left and right sides of the cabinet or enclosure. The horizontally-mounted rail tracks are preferably of sufficient length to accommodate the range of front-to-back rail adjustment, and span the interior width of the cabinet. In a preferred embodiment, three pairs of rail tracks are mounted on each side of the cabinet: an uppermost pair proximate the top of the cabinet, a center pair proximate the middle of the cabinet, and a lowermost pair proximate the bottom of the cabinet.

In cross-section, each of the horizontally-mounted rail tracks preferably resembles the letter “C,” and the uppermost and lowermost pairs of rail tracks preferably define indexing and positioning features. While not necessary for functionality, the center pair of rail tracks may also include these indexing and positioning features.

The indexing features of the rail tracks may be in the form of vertically-oriented index slots that are arrayed along approximately the entire length of the rail track. The vertically-oriented index slots may be preferably punched through the entire thickness of one return leg of the “C” structure, and may be spaced at quarter-inch increments. As described below, the vertically-oriented index slots may be dimensioned and disposed to interface with projecting index tabs on the vertical rack mount rails.

The positioning features of the rail tracks may be in the form of vertically-oriented positioning slots that are punched along the other return leg of the “C” structure, through the entire thickness of the return leg. The vertically-oriented positioning slots preferably resemble hash marks and may be spaced at quarter-inch increments. The positioning slots may be graduated in length and may repeat at one-inch intervals, such as the repetitive marks found on a typical twelve-inch ruler. The spacing of the positioning slots preferably corresponds to the spacing of the index slots.

Each of the vertically-mounted rail tracks also preferably defines a cutout portion or relief area in both return legs of the “C” structure. The cutout portion or relief areas allow the slidable connectors, described in detail below, to be inserted into the rail tracks. In a preferred embodiment, the cutout portions or relief areas are vertically aligned with one another and are located at the center of the length of the rail track, which is a position that is not typically used within a cabinet or enclosure.

In a preferred embodiment, two slidable connectors are positioned on each of the uppermost rail tracks, two slidable connectors are positioned on each of the center rail tracks, and two slidable connectors are positioned on each of the lowermost rail tracks. Each vertical triplet of slidable connectors, on an uppermost rail track, center rail track, and lowermost rail track, are preferably vertically aligned with one another.

The slidable connectors are preferably sized and shaped to ride within the “C” structure of the horizontally-mounted rail tracks and to freely traverse substantially the entire length of the rail tracks. The slidable connectors may be retained within the interior of the rail track by the return legs. In alternate embodiments, the slidable connectors may be configured and adapted to slide along the outer surface of the rail tracks, rather than riding within the rail track.

Each slidable connector preferably has an outwardly protruding male threaded post or stud in the approximate center of the slidable connector. When the slidable connector is in place within the rail track, the male threaded post or stud preferably protrudes beyond the return legs of the rail track, to allow the threaded stud to engage an opening in a vertical rack mount rail. A compression spring may be slid into place onto each of the threaded studs. The free length of the compression spring is preferably also sufficient to extend beyond the return legs of the rail track. Each slidable connector may also define two integral support tabs that also extend beyond the return legs of the rail track sufficient to engage corresponding slots in the vertical rack mount rail.

In a preferred embodiment, each cabinet includes four vertical rack mount rails, two on the right side of the enclosure and two on the left side. Each vertical rack mount rail preferably includes one or more vertical slots that interface with the support tabs on a slidable connector. When the vertical rack mount rail and the slidable connector are engaged, the surface of the rack mount rail may be in contact with the compression spring. The compression spring may be sufficiently long to push the rack mount rail away from the vertically-mounted rail track. When the vertical rack mount rail is in this extended position, the threaded studs preferably protrude through, and extend beyond, the surface of the vertical rack mount rail.

While still in this extended position, female threaded fasteners may be partially threaded onto the projecting male threaded studs. The female threaded fasteners are preferably left sufficiently loose so as to allow the vertical rack mount rail to remain extended from the horizontally-mounted rail track, due to the force from the compression spring. In this position, the vertical rack mount rail may be secured to the slidable connectors, but the combination of the vertical rack mount rail and the slidable connectors may be slid along the length of the rail track.

The slidable connectors are preferably colored such that they contrast with the color of the rail tracks. The contrasting colors allow a user to easily view a portion of the slidable connector, specifically an indicator band, through the positioning slots on the rail tracks, via a window on the vertical rack mount rails. The window on the vertical rack mount rail is preferably sufficiently wide to view a complete repetition of the positioning slots on the rail track.

In practice, the user slides the vertical rack mount rail into position until the windows at both ends of the vertical rack mount rails show that the contrasting-color indicator bands are aligned with the same positioning slot. In this position, the user is assured that the vertical rack mount rail is correctly positioned with respect to the top and bottom rail tracks. The user then tightens the female threaded fasteners, which overcomes the force of the compression springs, and forces the vertical rack mount rail against the rail tracks. This tightening of the female threaded fasteners also causes the projecting tabs on the vertical rack mount rail to engage the index slots on the rail tracks. The assembly process is repeated until all the vertical rack mount rails have been installed within the enclosure.

In a preferred embodiment, the invention provides an assembly for mounting electronic equipment within an enclosure, where the enclosure comprises a plurality of vertical structural members, and the assembly comprises a generally elongated rail track adapted to be coupled to at least one of the vertical structural members, where the rail track defines a generally planar interior surface, a pair of opposed longitudinal return legs, and a partially enclosed channel defined at least in part by the return legs and the interior surface. The assembly further comprises a connector defining a outwardly extending protrusion, where the connector is at least partially disposed within the partially enclosed channel of the rail track and a generally elongated rail coupled to the connector and to the rail track, where the rail defines a first opening that is configured to accept the protrusion of the connector and a plurality of mounting holes adapted for mounting electronic equipment.

In an aspect, the protrusion of the connector is a generally elongated post that extends in a direction that is generally perpendicular to a front face of the connector. In another aspect, the rail further defines an outwardly extending index tab and a first return leg of the rail track defines a plurality of indexing slots that are configured to accept the outwardly projecting index tab of the rail.

In yet another aspect, a second return leg of the rail track defines a plurality of positioning slots, a majority of the indexing slots are vertically aligned with a majority of the positioning slots, and at least a portion of the connector is visible through at least one of the positioning slots when the connector is disposed within the rail track channel.

In an aspect, a second return leg of the rail track defines a plurality of positioning slots, and at least a portion of the connector is visible through at least one of the positioning slots when the connector is disposed within the rail track channel. In another aspect, the rail further defines a second opening that is configured such that at least one of the positioning slots is visible through the second opening when the rail is coupled to the connector and the rail track.

In another aspect, the connector further defines an outwardly projecting support tab, and the rail further defines a second opening that is configured to accept the support tab of the connector. In still another aspect, the connector support tab extends in a direction that is generally perpendicular to a front face of the connector.

In an aspect, each of the return legs defines a cutout portion, and the two cutout portions are vertically aligned and together define an opening configured to accept the connector. In another aspect, the connector is configured to ride within and traverse the majority of the length of the partially enclosed channel of the rail track.

In an aspect, the connector further defines an outwardly extending sliding tab, where the sliding tab is configured to position a rear face of the connector away from the interior surface of the rail track. In another aspect, the protrusion of the connector is a generally elongated post and the assembly further comprises a spring placed over the elongated post, where the spring is configured to push the rail away from the rail track.

In another aspect, the protrusion of the connector is a male threaded generally elongated post, and the assembly further comprises a female threaded fastener adapted to fit onto the post, to secure the rail to the rail track. In still another aspect, the assembly further comprises a spring placed over the male threaded post, where the spring is configured to push the rail away from the rail track, and the fastener is configured to push the rail towards the rail track.

In another preferred embodiment, the invention provides an assembly for mounting electronic equipment within an enclosure, and the assembly comprises a pair of generally elongated rail tracks, where each rail track is adapted to be coupled to the enclosure such that the rail tracks are spaced apart from and generally parallel to each other, and where each rail track defines a generally planar interior surface, a pair of opposed longitudinal return legs, and a partially enclosed channel defined in part by the return legs and the interior surface. The assembly further comprises a pair of connectors, where each connector is at least partially disposed within the channel of one of the rail tracks and is configured to ride traverse the majority of the length of the channel, and where each connector defines a protrusion that extends outwardly from a front face of the connector. In addition, the assembly comprises a pair of generally elongated rails, where each rail is coupled to one of the rail tracks such that the rail tracks are spaced apart from each other, and where each rail defines a first opening that is configured to accept the protrusion of the connector and a plurality of mounting holes adapted for mounting electronic equipment.

In an aspect, the assembly further defines an outwardly extending protrusion, a first return leg of the rail track defines a plurality of indexing slots that are configured to accept the protrusion of the rail, and a second leg of the rail track defines a plurality of positioning slots, where a majority of the indexing slots are vertically aligned with a majority of the positioning slots. In addition, at least a portion of the connector is visible through at least one of the positioning slots when the connector is disposed within the rail track channel.

In another aspect, the protrusion of the connector is a threaded generally elongated post and the assembly further comprises a threaded fastener adapted to fit onto the post, to secure the rail to the rail track and a spring placed over the threaded post, where the spring is configured to push the rail away from the rail track, and the fastener is configured to push the rail towards the rail track.

In another preferred embodiment, the invention provides an enclosure for mounting electronic equipment, and the enclosure comprises a plurality of vertical structural members and a pair of generally elongated rail tracks, where each rail track is coupled to at least one vertical structural member such that the rail tracks are spaced apart from and generally parallel to each other and perpendicular to the vertical structural members, and where each rail track defines a generally planar interior surface, a pair of opposed longitudinal return legs, and a partially enclosed channel defined in part by the return legs and the interior surface. The enclosure further comprises a pair of generally elongated rails, where each rail is coupled to one of the rail tracks such that the rail tracks are spaced apart from and generally parallel to each other and perpendicular to the rail tracks, and where the rails are adapted for mounting electronic equipment. In addition, the enclosure comprises a pair of connectors, where each connector is at least partially disposed within the partially enclosed interior channel of one of the rail tracks and removably coupled to one of the rails.

In as aspect, each rail further defines an outwardly projecting index tab, a first return leg of at least one rail track defines a plurality of indexing slots that are configured to accept the projecting index tab of the rail, a second return leg of the at least one rail track defines a plurality of positioning slots, and at least some of the indexing slots are vertically aligned with some of the positioning slots. In addition, at least a portion of the connector is visible through at least one of the positioning slots when the connector is disposed within the rail track channel.

In another aspect, the connector further defines an outwardly extending protrusion, and the rail further defines a first opening configured to accept the protrusion of the connector and a second opening that is configured such that at least one of the positioning slots is visible through the second opening when the rail is coupled to the connector and the rail track.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a perspective view of a cabinet or enclosure with prior art horizontally-mounted rail tracks and prior art vertical rack mount rails;

FIG. 2 is perspective view of a cabinet or enclosure with preferred embodiments of the inventive horizontally-mounted rail tracks, vertical rack mount rails, and slidable connectors;

FIG. 3 is a perspective view of a preferred embodiment of an inventive horizontally-mounted rail track of the enclosure of FIG. 2;

FIG. 4 is a perspective view of a preferred embodiment of an inventive slidable connector of the enclosure of FIG. 2;

FIG. 5A is a perspective view of a preferred embodiment of an inventive vertical rack mount rail of the enclosure of FIG. 2;

FIG. 5B is a front view of the inventive vertical rack mount rail of FIG. 5A; and

FIGS. 6 through 12 show an exemplary assembly sequence for a preferred embodiment of an adjustable rail mounting system.

### DETAILED DESCRIPTION OF THE PREFERRED EMBODIMENTS OF THE INVENTION

### I. Prior Art Cabinet or Enclosure

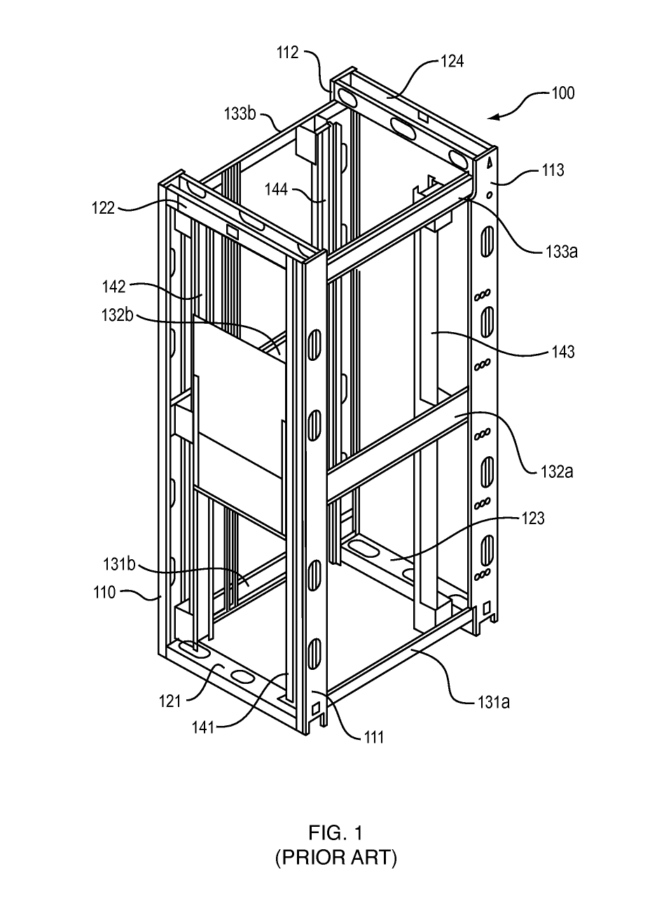

A prior art cabinet or enclosure 100 is shown in FIG. 1. Cabinet or enclosure 100 comprises two vertical front enclosure structural members 110 and 111, two vertical rear enclosure structural members 112 and 113, two horizontal front enclosure structural members 121 and 122, and two horizontal rear enclosure structural members 123 and 124. The structural members (110, 111, 112, 113, 121, 122, 123, and 124) together form the generally parallelepiped exterior frame of enclosure 100.

Prior art enclosure 100 also comprises three pairs of prior art horizontally-mounted rail tracks: lowermost rail tracks 131a and 131b, center rail tracks 132a and 132b, and uppermost rail tracks 133a and 133b. The pairs of horizontally-mounted rail tracks are mounted substantially parallel to each other in a front-to-back orientation, along the left and right sides of enclosure 100.

Prior art enclosure 100 further comprises two pairs of prior art vertical rack mount rails: front rack mount rails 141 and 142, and rear rack mount rails 143 and 144. Two of the vertical rack mount rails are installed on the left interior side of enclosure 100 (142 and 144), and the other two vertical rack mount rails are installed on the right interior side of enclosure 100 (141 and 143).

As is known in the art, electronic components are typically mounted and secured to the vertical rack mount rails (141, 142, 143 and 144).

II. Cabinet or Enclosure with Inventive Rail Tracks, Rack Mount Rails, and Slidable Connectors

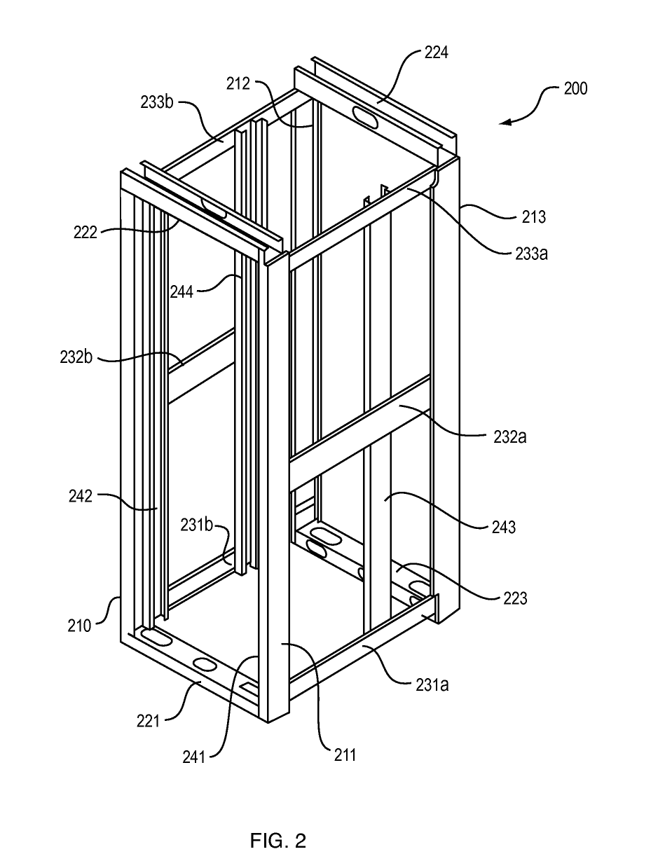

A cabinet or enclosure 200 with preferred embodiments of the inventive horizontally-mounted rail tracks, vertical rack mount rails and slidable connectors is shown in FIG. 2. Enclosure 200 comprises structural members that are functionally similar to the structural members shown in FIG. 1, namely: two vertical front enclosure structural members 210 and 211, two vertical rear enclosure structural members 212 and 213, two horizontal front enclosure structural members 221 and 222, and two horizontal rear enclosure structural members 223 and 224. As with prior art enclosure 100, the structural members (210, 211, 212, 213, 221, 222, 223 and 224) together form the generally parallelepiped exterior frame of enclosure 200.

In a preferred embodiment, enclosure 200 also comprises three pairs of inventive horizontally-mounted rail tracks: lowermost rail tracks 231a and 231b, center rail tracks 232a and 232b, and uppermost rail tracks 233a and 233b. The pairs of horizontally-mounted rail tracks are mounted substantially parallel to each other in a front-to-back orientation, along the left and right sides of enclosure 200, and are coupled to the vertical enclosure structural members (210, 211, 212 and 213) of the enclosure 200. The horizontally-mounted rail tracks are preferably of sufficient length to accommodate the range of front-to-back rail adjustment, and preferably span the approximate interior width of cabinet or enclosure 200. Note that the horizontally-mounted rail tracks need not be mounted in pairs, and the invention is not limited to any particular number of horizontally-mounted rail tracks.

In a preferred embodiment, enclosure 200 also comprises two pairs of inventive vertical rack mount rails: front rack mount rails 241 and 242, and rear rack mount rails 243 and 244. Rails 242 and 244 are located on the interior left side of the enclosure, and rails 241 and 243 are located on the interior right side of the enclosure. Note, however, that the invention is not limited to any particular number of vertical rack mount rails. In addition, while the vertical rack mount rails preferably span the approximate interior height of the enclosure, from the lowermost rail tracks (231a, 231b) to the uppermost rail tracks (233a, 233b), half-height vertical rack mount rails, extending from the lowermost rail tracks (231a, 231b) to the center rail tracks (232a, 232b), or from the center rail tracks (232a, 232b) to the uppermost rail tracks (233a, 233b), are within the scope of the invention.

The horizontally-mounted rail tracks (231a, 231b, 232a, 232b, 233a and 233b) are configured and adapted to support the weight of the vertical rack mount rails (241, 242, 243 and 244) and their electronic equipment loads, and to facilitate the fore and aft adjustment of the vertical rack mount rails, as described in detail below.

The vertical rack mount rails (241, 242, 243, and 244) are coupled to the horizontally-mounted rail tracks (231a, 231b, 232a, 232b, 233a and 233b) by the slidable connectors, as described in detail below.

### III. Horizontally-Mounted Rail Track

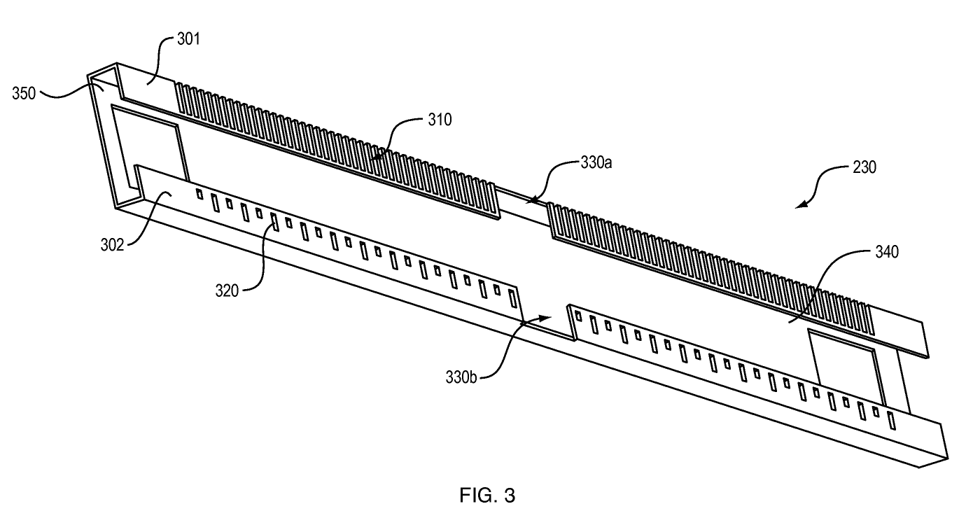

A preferred embodiment of a horizontally-mounted rail track 230 is shown in FIG. 3, and is representative of lowermost rail tracks 231a and 231b and uppermost rail tracks 233a and 233b.

Horizontally-mounted rail track 230 defines a generally elongated body with a generally planar interior wall or surface 340 and two opposed, longitudinal return legs 301 and 302, such that rail track 230 is generally “C”-shaped in cross-section. The return legs 301 and 302 span essentially the entire length of the rail track 230. The planar interior surface 340 and the opposed return legs 301 and 302 together define a partially enclosed space or channel 350 that is disposed and dimensioned to receive a slidable connector 410, as described in detail below.

Horizontally-mounted rail track 230 further comprises indexing features in the form of vertically-oriented index slots, represented by index slot 310, and positioning features in the form of vertically-oriented positioning slots that resemble hash marks, represented by positioning slot 320.

While center rail tracks 232a and 232b may also be represented by horizontally-mounted rail track 230, and include the vertically-oriented index slots and/or vertically-oriented positioning slots, these two sets of features are not functionally required when the enclosure 200 includes full-height vertical rack mount rails.

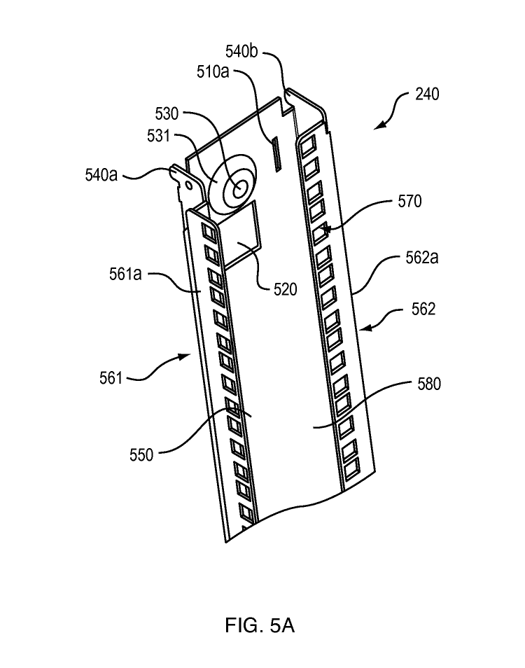

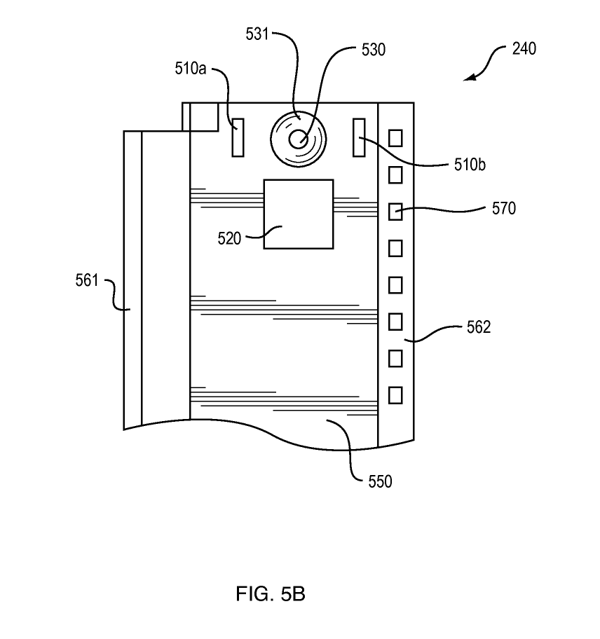

As shown in FIG. 3, the indexing features of horizontally-mounted rail track 230 are in the form of vertically-oriented index slots, of which rail track index slot 310 is representative. In a preferred embodiment, the vertically-oriented index slots are punched through the entire thickness of first return leg 301 of the rail track 230 and are spaced at quarter-inch intervals. While quarter-inch increments are easily interpreted by users in the United States, this is not a limitation, and the vertically-oriented index slots may be spaced at any other uniform unit of measure, including metric units. As described below and with reference to FIGS. 5A and 5B, the vertically-oriented index slots 310 interface with projecting index tabs 540a and 540b on the vertical rack mount rails 241, 242, 243 and 244.

With further reference to FIG. 3, the positioning features of horizontally-mounted rail track 230 are in the form or vertically-oriented positioning slots, of which positioning slot 320 is representative. In a preferred embodiment, the vertically-oriented positioning slots are punched through the entire thickness of a second return leg 302 of the rail track 230. The vertically-oriented positioning slots are preferably spaced at quarter-inch intervals, and are graduated in length and repeat at one-inch intervals, similar to the repetitive marks found on a typical twelve-inch ruler. Specifically, and in a preferred embodiment, the slots at one-inch intervals are longest in length, the slots at half-inch intervals are shorter than the slots at one-inch intervals, and the slots at quarter-inch intervals are shorter than the slots at half-inch intervals. The quarter-inch spacing of the vertically-oriented positioning slots corresponds to the vertically-oriented index slots, such that the positioning slots and the index slots are vertically aligned. As with the vertically-oriented index slots, the quarter-inch spacing is not a limitation, and the vertically-oriented positioning slots, such as positioning slot 320, may be spaced at any other uniform unit of measure, including metric units.

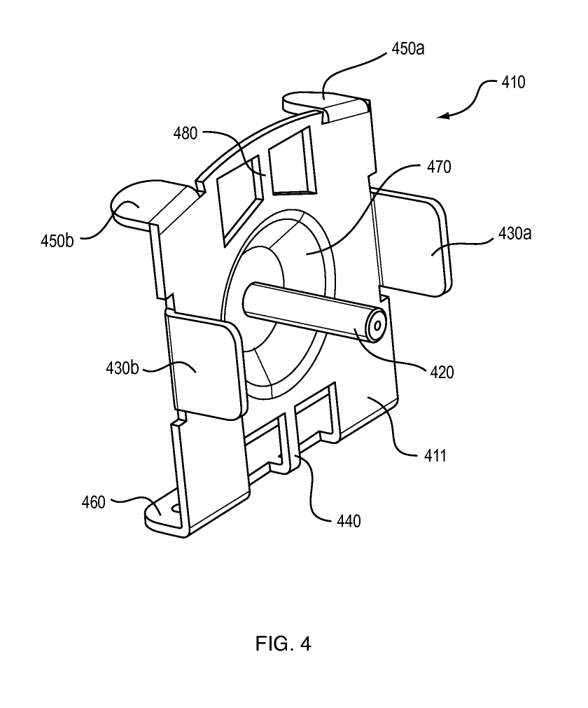

Horizontally-mounted rail track 230 also comprises two cutout portions or relief areas 330a and 330b, one in each return leg, 301 and 302 respectively, of rail track 230. As described below, cutout portions or relief areas 330a and 330b are sized and shaped to allow a slidable connector 410, shown in FIG. 4, to be inserted into the rail track 230. The slidable connectors are dimensioned so as to be retained within the interior of the rail track 230 by the return legs 301 and 302.

In a preferred embodiment, cutout portions or relief areas 330a and 330b are vertically aligned with each other and are located at the approximate center of rail track 230, so as to define an opening dimensioned to receive the slidable connector. As is known in the art, the center of a horizontally-mounted rail track is not typically used within a cabinet or enclosure. This is not a limitation of the invention, however, and the cutout portions or relief areas 301 and 302 may be located elsewhere along the length of the rail track 230.

Note that the orientation of the horizontally-mounted rail track 230 is dependent upon whether the rail track 230 is installed for use as an uppermost rail track 233a and 233b or a lowermost rail track 231a and 231b. When used as an uppermost rail track, horizontally-mounted rail track 230 is installed as shown in FIG. 3, with the vertically-oriented index slots 310 on top. When used as a lowermost rail track, horizontally-mounted rail track 230 is turned upside down, with the vertically-oriented positioning slots 320 on top.

### IV. Slidable Connector

A preferred embodiment of a slidable connector 410 is shown in FIG. 4. Slidable connector 410 is generally rectangular in shape and defines an outwardly extending protruding male threaded post or stud 420, one or more outwardly extending protruding integral support tabs 430a and 430b, one or more outwardly extending protruding upper sliding tabs 450a and 450b, one or more outwardly extending protruding lower sliding tabs 460, a first indicator band 440, and a second indicator band 480. In a preferred embodiment, male threaded stud 420 and integral support tabs 430a and 430b extend in a first direction generally perpendicular to the face of connector 410, and upper sliding tabs 450a and 450b and protruding lower sliding tabs 460 extend in a second opposite direction generally perpendicular to the face of connector 410.

The slidable connectors 410 are preferably colored such that they contrast with the color of the horizontally-mounted rail tracks 230. The contrasting colors allow a user to easily view a portion of the slidable connector, specifically the indicator bands 440 and 480, through the vertically-oriented positioning slot 320 on the horizontally-mounted rail tracks 230, via a window 520 on the vertical rack mount rails 240, shown in FIGS. 5A and 5B. The window 520 on the vertical rack mount rail 240 is sufficiently wide to view a complete repetition of the vertically-oriented positioning slots on the horizontally-mounted rail track 230. Note that two indicator bands 440 and 480 are required to accommodate the two orientations of the horizontally-mounted rail track 230, as described above.

Slidable connector 410 is sized and shaped to ride within and freely traverse the majority of the length of the channel 350 of a horizontally-mounted rail track, such as track 230. Upper sliding tabs 450a and 450b and lower sliding tab 460 enable the slidable connector 410 to fill substantially the entire depth of the channel. When slidable connector 410 is inserted into the rail track 230 at cutout portion or relief areas 330a and 330b, upper sliding tabs 450a and 450b and lower sliding tab 460 function to position the front face 411 of the slidable connector 410 forward, proximate the return legs 310 and 320 of the rail track 230 and away from the interior surface 340 of the rail track 230.

In a preferred embodiment, two slidable connectors are positioned on each of the uppermost rail tracks 233a and 233b, two slidable connectors are positioned on each of the center rail tracks 232a and 232b, and two slidable connectors are positioned on each of the lowermost rail tracks 231a and 231b. Each vertical triplet of slidable connectors, one each on an uppermost rail track, center rail track, and lowermost rail track, are vertically aligned with one another.

As shown in FIG. 4, outwardly protruding male threaded post or stud 420 is integrally pressed into place in a recessed area 470 proximate the center of the slidable connector. The recessed area 470 accommodates compression spring 610, described below. When the slidable connector 410 is in place within rail track 230, male threaded stud 420 extends beyond the return legs 301 and 302 of horizontally-mounted rail track 230, to allow the male threaded stud 420 to engage an opening 530 in a vertical rack mount rail, as shown in FIG. 5A and described below.

In a preferred embodiment, slidable connector 410 also defines two integral support tabs 430a and 430b that also extend beyond the return legs 301 and 302 of horizontally-mounted rail track 230, to engage corresponding slots 510a and 510b in a vertical rack mount rail 240, as shown in FIG. 5B and described below.

### V. Vertical Rack Mount Rail

An end portion of a preferred embodiment of a vertical rack mount rail 240 is shown in FIGS. 5A and 5B, and is representative of the top and bottom end portions of vertical rack mount rails 241, 242, 243 and 244. The vertical rack mount rails defines a generally elongated body 550 and a pair of opposed flanges 561 and 562. The flanges 561 and 562 are generally perpendicular to and extend away from the front wall or surface 580 of the vertical mount rail.

In a preferred embodiment, the flanges 561 and 562 extend substantially along the length of the rail 240 and define a plurality of mounting holes 570 configured and adapted for mounting the electronic equipment. The mounting holes on flange 561 are defined in a member 561a that is generally perpendicular to the generally planar interior front wall or front surface 580, and the mounting holes on flange 562 are defined in a member 562a that is generally parallel to the front surface 580. In a preferred embodiment, the vertical rack mount rails, and the mounting holes, conform to EIA standards, such as EIA-310-D.

The elongated body of vertical rack mount rail 240 defines, proximate each end, one or more integral slots 510a and 510b, interface area 531, opening 530, and window 520. Each end of vertical rack mount rail 240 also defines projecting index tabs 540a and 540b that are generally perpendicular to and extend away from the rear surface of the vertical mount rail.

Integral slots 510a and 510b are sized and shaped to accommodate the integral support tabs 430a and 430b, respectively, on slidable connector 410, and opening 530 is sized and shaped to accommodate male threaded post or stud 420 on slidable connector 410. Projecting index tabs 540a and 540b are sized and shaped to fit through one of the index slots, such as index slot 310, on a horizontally-mounted rail track, such as rail track 230.

As described previously, in a preferred embodiment, center rail tracks 232a and 232b differ from the uppermost rail tracks 233a and 233b and the lowermost rail tracks 231a and 231b in that they do not include the vertically-oriented index slots or vertically-oriented positioning slots. Correspondingly, in a preferred embodiment, the approximate center portion of each vertical rack mount rail does not include all of the features of the end portions of the vertical rack mount rail, specifically a window, such as window 520, or projecting index tabs, such as index tabs 540a and 540b. Instead, the approximate center portion of vertical rack mount rail 240 defines two integral slots that are substantially identical to integral slots 510a and 510b, an interface area that is substantially identical to interface area 531, and an opening that is substantially identical to opening 520. As with the end portions of vertical rack mount rail 240, the integral slots in the approximate center portion of the vertical rack mount rail are sized and shaped to accommodate the integral support tabs 430a and 430b on slidable connector 410, and the opening in the approximate center portion is sized and shaped to accommodate male threaded stud 420 on slidable connector 410.

### VI. Assembly Sequence

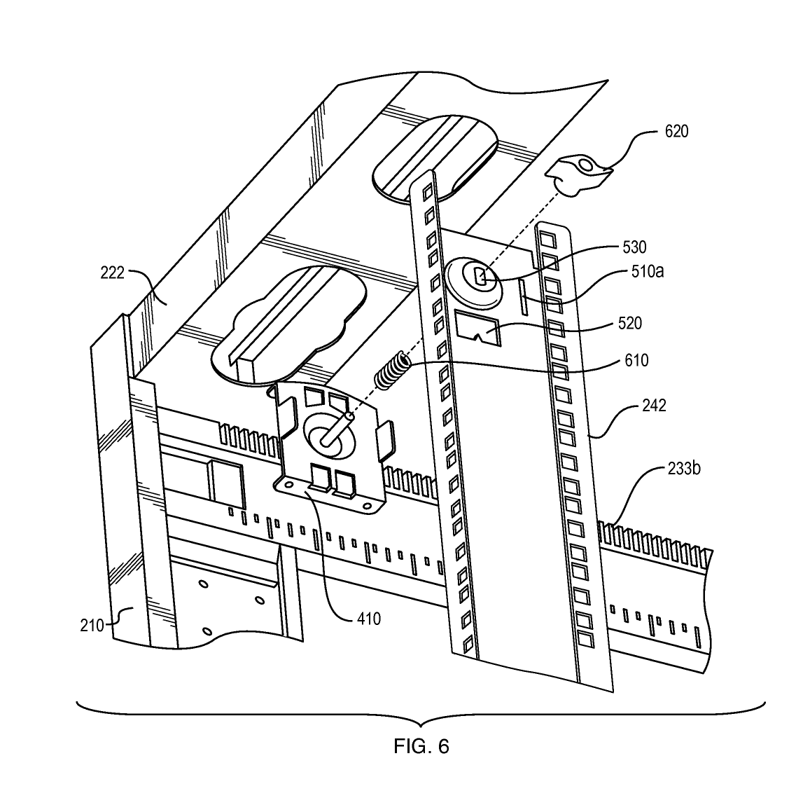

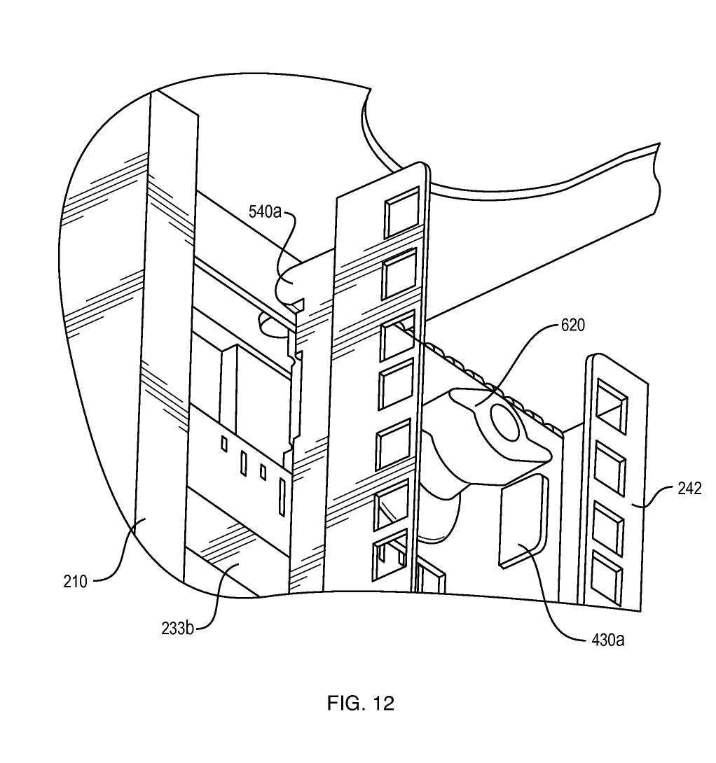

FIGS. 6 through 12 show an exemplary assembly sequence for a preferred embodiment of an adjustable rail mounting system. FIG. 6 shows left uppermost horizontally-mounted rail track 233b coupled to vertical front enclosure structural member 210, and vertical front enclosure structural member 210 coupled to horizontal front enclosure structural member 222. Also shown in FIG. 6 are slidable connector 410, compression spring 610, female threaded fastener 620, and vertical rack mount rail 242 with integral slot 510a, window 520, and opening 530.

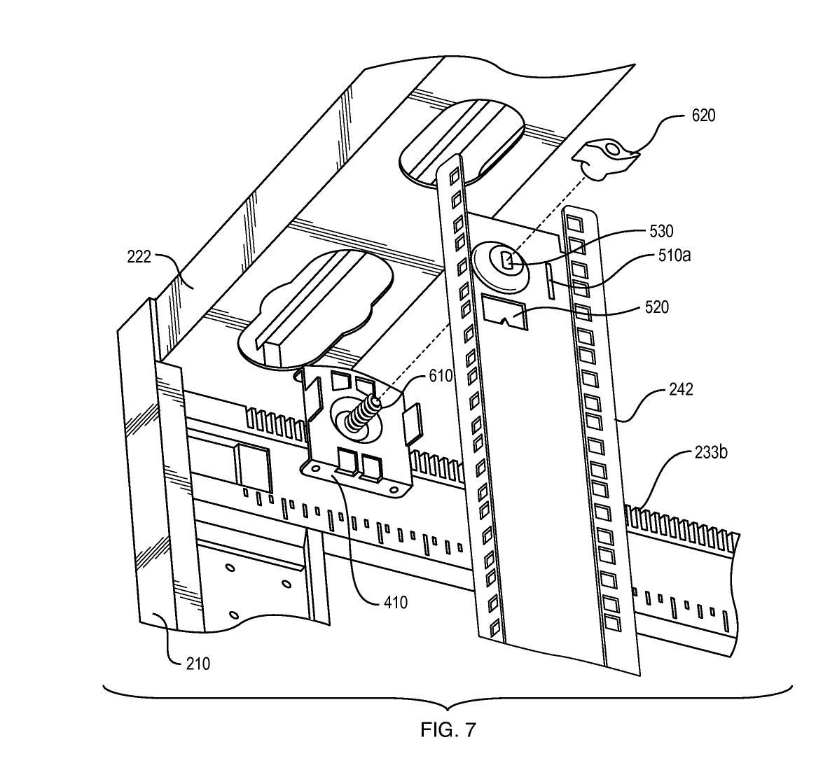

In the next step, shown in FIG. 7, compression spring 610 has been placed over male threaded post or stud 420 of the slidable connector 410. In an alternate embodiment, the compression spring 610 may be placed over the male threaded stud 420 after the slidable connector 410 has been inserted onto the rail track.

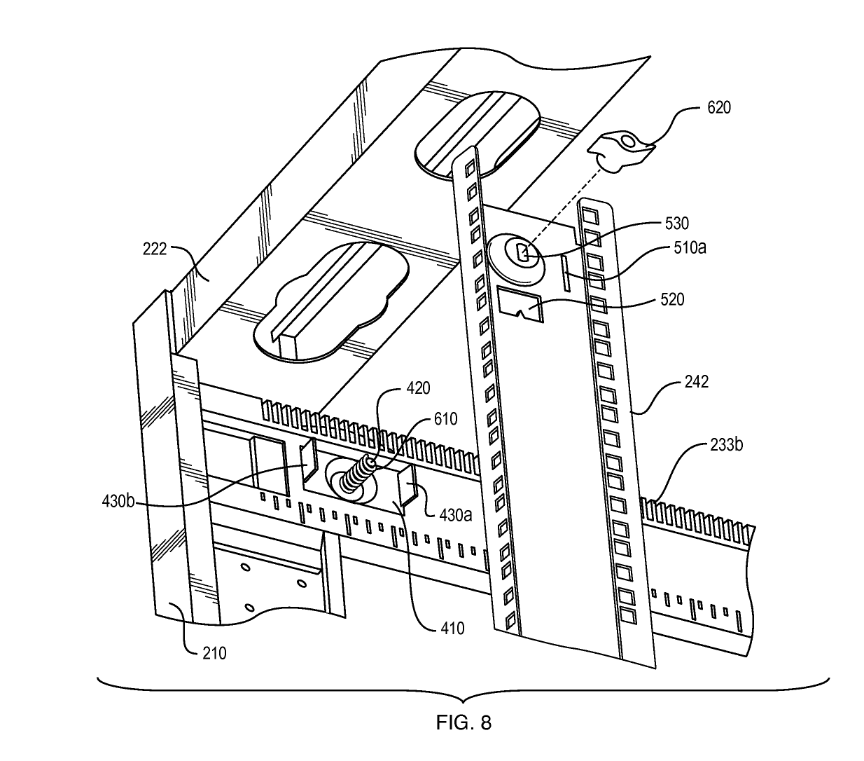

In FIG. 8, the slidable connector 410 has been inserted into horizontally-mounted rail track 233b at the cutout portions or relief areas 330a and 330b and slid within the rail track 233b towards vertical front enclosure structural member 210. Note that the free length of compression spring 610, when placed over the male threaded post or stud 420, is sufficient to extend beyond return legs 301 and 302 of horizontally-mounted rail track 233b.

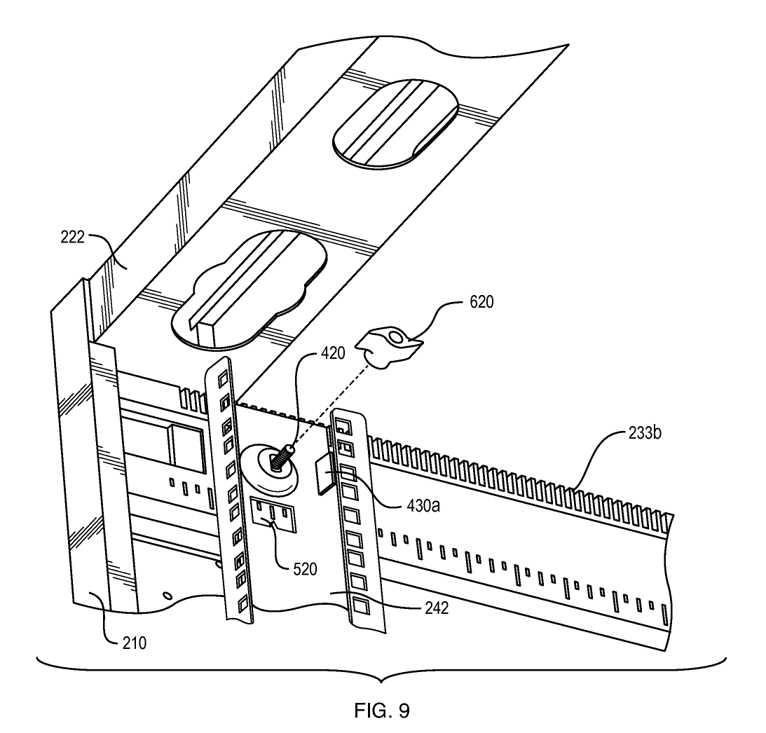

In FIG. 9, vertical rack mount rail 242 has been placed onto horizontally-mounted rail track 233b and slidable connector 410, such that the integral slots 510a and 510b of the vertical rack mount rail 242 engage the integral support tabs 430a and 430b, respectively, of slidable connector 410. In this extended position, the internal surface of interface area 531 contacts the compression spring 610, and the distal portion of the male threaded stud 420 extends through the opening 530. Compression spring 610 provides sufficient force to push vertical rack mount rail 242 away from the interior surface 340 of rail track 233b, such that the projecting index tabs 540a and 540b on the vertical rack mount rail 233b do not engage the index slots 310 on the horizontally-mounted rail track 233b.

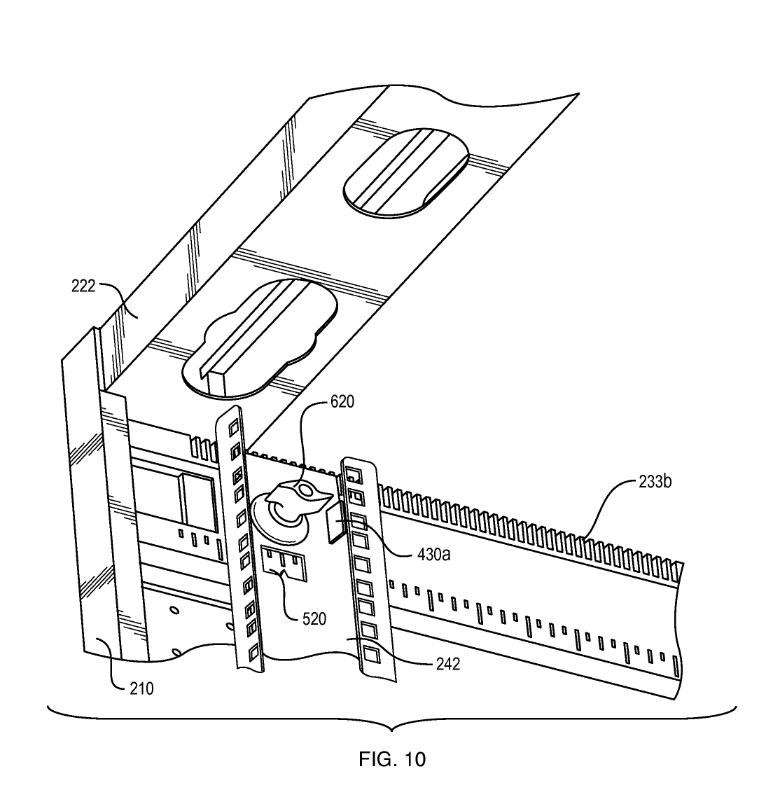

In FIG. 10, female threaded fastener 620 has been partially threaded onto male threaded stud 420. Female threaded fastener 620 has been left sufficiently loose to allow vertical rack mount rail 242 to remain extended from horizontally-mounted rail track 233b, under pressure from compression spring 610. In this position, the vertical rack mount rail 242 is loosely coupled to the slidable connector 410, and the combination of the vertical rack mount rail and the slidable connector is capable of sliding along the length of the horizontally-mounted rail track 233b.

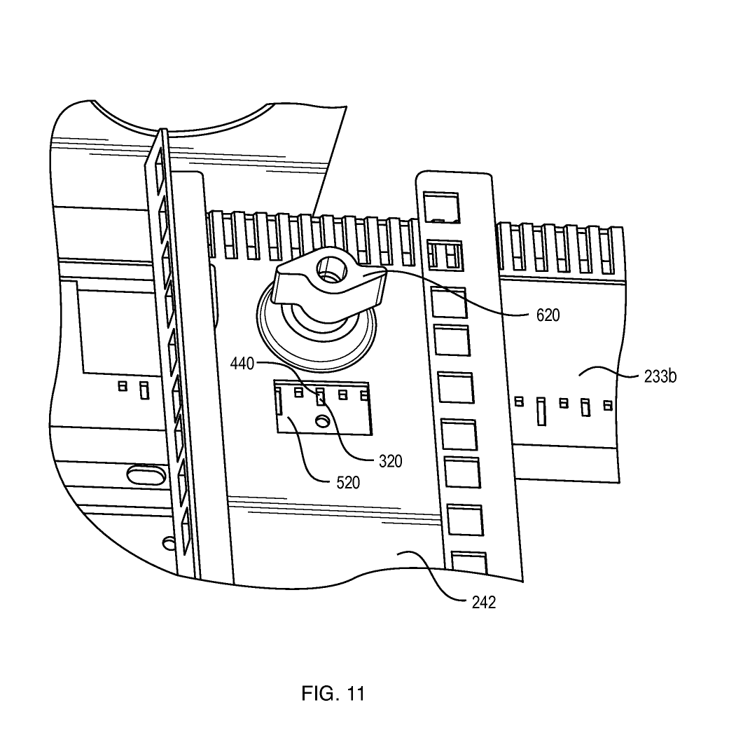

In FIG. 11, the user has slid the vertical mount rail 242 into position, such that the windows 520 at both ends of the vertical rack mount rail 242 show that the contrasting-color indicator bands 440 are aligned with the same positioning slot 320 on the horizontally-mounted rail track 233b. In this position, the user is assured that the vertical rack mount rail 242 is correctly positioned with respect to the top and bottom horizontally-mounted rail tracks 233b and 231b. The user then tightens the female threaded fastener 620, which overcomes the force of the compression spring 610, and forces the vertical rack mount rail 242 against the horizontally-mounted rail track 233b. This tightening of the female threaded fastener 620 also causes projecting tabs 540a and 540b on the vertical rack mount rail to engage the index slots, e.g., 310, on the horizontally-mounted rail track 233b.

The assembly process is repeated until all four vertical rack mount rails (241, 242, 243 and 244) have been mounted within the cabinet 200, at which point the vertical rack mounts rails are ready for the installation of the electronic equipment.

The particular construction, materials and dimensions described herein are not limitations of the invention, as other constructions can accomplish the invention described herein.

Although specific features of the invention are shown in some figures and not others, this is for convenience only, as some features may be combined with any or all of the other features in accordance with the invention.

Recitation ranges of values herein are merely intended to serve as a shorthand method of referring individually to each separate value falling within the range, unless otherwise indicated herein, and each separate value is incorporated into the specification as if it were individually recited herein.

The use of any and all examples, or exemplary language (e.g., “such as”) provided herein, is intended merely to better illustrate the invention and does not pose a limitation on the scope of the invention.

A variety of modifications to the embodiments described herein will be apparent to those skilled in the art from the disclosure provided herein. Thus, the invention may be embodied in other specific forms without departing from the spirit or essential attributes thereof.

What is claimed is:

1. An assembly for mounting electronic equipment within an enclosure, the enclosure comprising a plurality of vertical structural members, the assembly comprising:
a generally elongated rail track adapted to be coupled to at least one of the vertical structural members, where the rail track defines a generally planar interior surface, a pair of opposed longitudinal return legs, and a partially enclosed channel defined at least in part by the return legs and the interior surface;
a connector defining a outwardly extending protrusion, where the connector is at least partially disposed within the partially enclosed channel of the rail track; and
a generally elongated rail coupled to the connector and to the rail track, where the rail defines a first opening that is configured to accept the protrusion of the connector and a plurality of mounting holes adapted for mounting electronic equipment.

2. The assembly of claim 1, where the protrusion of the connector is a generally elongated post that extends in a direction that is generally perpendicular to a front face of the connector.

3. The assembly of claim 1,
where the rail further defines an outwardly extending index tab; and
where a first return leg of the rail track defines a plurality of indexing slots that are configured to accept the outwardly projecting index tab of the rail.

4. The assembly of claim 3,
where a second return leg of the rail track defines a plurality of positioning slots, and where a majority of the indexing slots are vertically aligned with a majority of the positioning slots; and
where at least a portion of the connector is visible through at least one of the positioning slots when the connector is disposed within the rail track channel.

5. The assembly of claim 1,
where a second return leg of the rail track defines a plurality of positioning slots; and
where at least a portion of the connector is visible through at least one of the positioning slots when the connector is disposed within the rail track channel.

6. The assembly of claim 5,
where the rail further defines a second opening that is configured such that at least one of the positioning slots is visible through the second opening when the rail is coupled to the connector and the rail track.

7. The assembly of claim 1,
where connector further defines an outwardly projecting support tab; and
where the rail further defines a second opening that is configured to accept the support tab of the connector.

8. The assembly of claim 7, where the connector support tab extends in a direction that is generally perpendicular to a front face of the connector.

9. The assembly of claim 1,
where each of the return legs defines a cutout portion, and the two cutout portions are vertically aligned and together define an opening configured to accept the connector.

10. The assembly of claim 1,
where the connector is configured to ride within and traverse the majority of the length of the partially enclosed channel of the rail track.

11. The assembly of claim 1,
where the connector further defines an outwardly extending sliding tab, where the sliding tab is configured to position a rear face of the connector away from the interior surface of the rail track.

12. The assembly of claim 1,
where the protrusion of the connector is a generally elongated post and the assembly further comprises a spring placed over the elongated post, where the spring is configured to push the rail away from the rail track.

13. The assembly of claim 1,
where the protrusion of the connector is a male threaded generally elongated post, and the assembly further comprises a female threaded fastener adapted to fit onto the post, to secure the rail to the rail track.

14. The assembly of claim 13, further comprising a spring placed over the male threaded post, where the spring is configured to push the rail away from the rail track, and the fastener is configured to push the rail towards the rail track.

15. An assembly for mounting electronic equipment within an enclosure, the assembly comprising:
a pair of generally elongated rail tracks, each rail track adapted to be coupled to the enclosure such that the rail tracks are spaced apart from and generally parallel to each other, where each rail track defines a generally planar interior surface, a pair of opposed longitudinal return legs, and a partially enclosed channel defined in part by the return legs and the interior surface;
a pair of connectors, each connector at least partially disposed within the channel of one of the rail tracks and configured to ride traverse the majority of the length of the channel, where each connector defines a protrusion that extends outwardly from a front face of the connector; and
a pair of generally elongated rails, each rail coupled to one of the rail tracks such that the rail tracks are spaced apart from each other, where each rail defines a first opening that is configured to accept the protrusion of the connector and a plurality of mounting holes adapted for mounting electronic equipment.

16. The assembly of claim 15,
where the rail further defines an outwardly extending protrusion;
where a first return leg of the rail track defines a plurality of indexing slots that are configured to accept the protrusion of the rail;
where a second return leg of the rail track defines a plurality of positioning slots, and where a majority of the indexing slots are vertically aligned with a majority of the positioning slots; and
where at least a portion of the connector is visible through at least one of the positioning slots when the connector is disposed within the rail track channel.

17. The assembly of claim 16,
where the protrusion of the connector is a threaded generally elongated post, and the assembly further comprises a threaded fastener adapted to fit onto the post, to secure the rail to the rail track; and
the assembly further comprises a spring placed over the threaded post, where the spring is configured to push the rail away from the rail track, and the fastener is configured to push the rail towards the rail track.

18. An enclosure for mounting electronic equipment, the enclosure comprising:
a plurality of vertical structural members;
a pair of generally elongated rail tracks, each rail track coupled to at least one vertical structural member such that the rail tracks are spaced apart from and generally parallel to each other and perpendicular to the vertical structural members, where each rail track defines a generally planar interior surface, a pair of opposed longitudinal return legs, and a partially enclosed channel defined in part by the return legs and the interior surface;
a pair of generally elongated rails, each rail coupled to one of the rail tracks such that the rail tracks are spaced apart from and generally parallel to each other and perpendicular to the rail tracks, where the rails are adapted for mounting electronic equipment; and
a pair of connectors, each connector at least partially disposed within the partially enclosed interior channel of one of the rail tracks and removably coupled to one of the rails.

19. The enclosure of claim 18,
where each rail further defines an outwardly projecting index tab;
where a first return leg of at least one rail track defines a plurality of indexing slots that are configured to accept the projecting index tab of the rail;
where a second return leg of the at least one rail track defines a plurality of positioning slots, and where at least some of the indexing slots are vertically aligned with some of the positioning slots; and
where at least a portion of the connector is visible through at least one of the positioning slots when the connector is disposed within the rail track channel.

20. The enclosure of claim 19,
where the connector further defines an outwardly extending protrusion; and
where the rail further defines a first opening configured to accept the protrusion of the connector and a second opening that is configured such that at least one of the positioning slots is visible through the second opening when the rail is coupled to the connector and the rail track.
